(19) United States
(12) Patent Application Publication
(10) Pub. No.: US 2010/0264975 A1
(43) Pub. Date: Oct. 21, 2010

(54) Level Shifter with Rise/Fall Delay Matching

(76) Inventor: Gregory S. Scott, Santa Clara, CA (US)

Correspondence Address: Meyertons, Hood, Kivlin, Kowert & Goetzel, P.C., The Chase Building, 700 Lavaca, Suite 800, Austin, TX, 78701-3102, US

(21) Appl. No.: 12/425,712

(22) Filed: Apr. 17, 2009

(51) Int. Cl. H03L 5/00

(52) U.S. Cl. 327/333

(57) ABSTRACT

In one embodiment, a level shifter circuit is provided that may include approximately matched rising edge and falling edge delays through the level shifter. The level shifter may also have a low delay and low power consumption. The level shifter circuit may include a pair of low voltage input inverters coupled to a pulldown transistor, where a node between the low voltage input inverters is coupled through another pulldown stack to a pullup transistor. Including an output inverter, both rising transitions and falling transitions may include about 4 gate delays in one embodiment. The level shifter may include keeper transistors to turn off the pullup transistor after the pullup is performed, and the pulldown transistor may be turned off as the pullup transistor is turned on. The pullup and pulldown transistors may not drive against each other during operation, which may reduce power consumption in the circuit.

### BACKGROUND

1. Field of the Invention

This invention is related to the field of integrated circuits and, more/particularly, level shifter circuits in integrated circuits.

2. Description of the Related Art

Integrated circuits generally include core circuitry that implements the operation for which the integrated circuit is designed, driver circuitry to drive output signals from the integrated circuit to external circuitry, and receiver circuits to receive input signals from external circuitry. The driver/receiver circuitry buffers and isolates the core circuitry from the external circuitry, handling the larger loads, higher current flows, higher voltages, noise, etc. involved in external communication.

Originally, the core circuitry operated with the same power supply voltage as the driver/receiver circuitry. However, as semiconductor fabrication technology continued to evolve and transistor feature sizes continued to be reduced, the core circuitry eventually required power supply voltages lower than those that could be used for communicating with the external circuitry. In some cases, backward compatibility with legacy external circuitry that was not manufactured using the most advanced semiconductor fabrication technology was desired. In other cases, a higher communication voltage is required by the effects of noise and other factors that affect the reliability of external communications.

The driver/receiver circuitry designs have changed to handle the differences in internal supply voltages and external communication voltages. For example, transistors used in the driver/receiver circuitry can implement feature sizes that are larger than the transistors used in the core circuitry, to safely handle the higher voltages. Level shifting techniques can be used to translate signals from the core circuitry domain to the driver/receiver domain, and vice versa.

### SUMMARY

In one embodiment, a level shifter circuit is provided that may include approximately matched rising edge and falling edge delays through the level shifter. The level shifter may also have a low delay and low power consumption. The level shifter circuit may include a pair of low voltage input inverters coupled to a pulldown transistor, where a node between the low voltage input inverters is coupled through another pulldown stack to a pullup transistor. Including an output inverter, both rising transitions and falling transitions may include about 4 gate delays in one embodiment. The level shifter may include keeper transistors to turn off the pullup transistor after the pullup is performed, and the pulldown transistor may be turned off as the pullup transistor is turned on. The pullup and pulldown transistors may not drive against each other during operation, which may reduce power consumption in the circuit.

### BRIEF DESCRIPTION OF THE DRAWINGS

The following detailed description makes reference to the accompanying drawings, which are now briefly described.

FIG. 1 is a block diagram of one embodiment of an integrated circuit.

FIG. 2 is a circuit diagram of one embodiment of a level shifter circuit that may be used in the integrated circuit of FIG. 1.

FIG. 3 is a timing diagram illustrating exemplary operation of one embodiment of the level shifter circuit shown in FIG. 2.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include”, “including”, and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits and/or memory storing program instructions executable to implement the operation. The memory can include volatile memory such as static or dynamic random access memory and/or nonvolatile memory such as optical or magnetic disk storage, flash memory, programmable read-only memories, etc. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six interpretation for that unit/circuit/component.

### DETAILED DESCRIPTION OF EMBODIMENTS

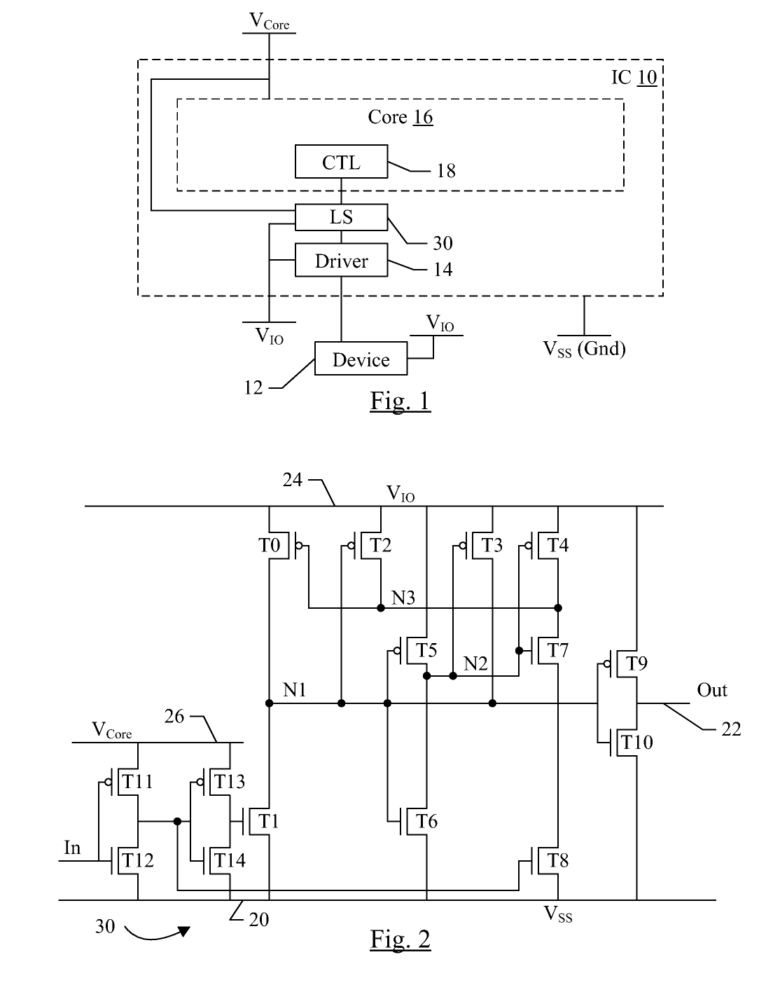

Turning now to FIG. 1, a block diagram of a system including one embodiment of an integrated circuit (IC) 10 and an external device 12 is shown. The integrated circuit 10 includes an output pin to which the device 12 is coupled (e.g. via a conductor on a board to which the integrated circuit 10 and the device 12 are mounted, via a connector cable, etc.). A driver circuit 14 in the integrated circuit 10 is connected to an output pad of the integrated circuit 10, to which the pin may be connected when the integrated circuit 10 is packaged. The integrated circuit further includes core circuitry 16, which includes control circuit 18. The control circuit 18 is coupled to a level shifter circuit 30 that is coupled to the driver circuit 14. Specifically, the control circuit 18 may provide one or more control signals to the level shifter 30, which may level shift the signals and provide the level-shifted signals to the driver circuit 14. Specifically, there may be an instance of the level shifter 30 for each signal to be level shifted from the V_{Core} voltage domain to the V_{IO} voltage domain. The driver circuit 18 is supplied by a supply voltage V_{IO} that is used to communicate with the external device 12 on the output pin, and the core circuitry 16 is supplied by a V_{Core} supply voltage. The external device 12 is also supplied by the V_{IO} supply voltage. The level shifter 30 is supplied with both the V_{IO} and V_{Core} supply voltages. The integrated circuit is further supplied with a V_{SS} supply voltage (e.g. ground) to which the V_{IO} and V_{Core} voltages are referenced. The magnitude of the V_{IO} supply voltage may be higher than the magnitude of the V_{Core} supply voltage during use. For example, the V_{IO} supply voltage may be about 3.3 volts, and the V_{Core} supply voltage may be about 1.8 volts, or even less such as about 1.0 volts. In another implementation, the V_{IO} supply voltage may be about 1.2 volts, and the V_{Core} voltage may be about 0.55 volts up to about 1.0 volts. Any combination of V_{IO} and V_{Core} supply voltage magnitudes may be used in various embodiments.

The driver circuit 14 may receive the signal or signals from the level shifter 30, and may drive the output high or low (or tristate the output) in response to the level-shifted signals. Generally, a control signal may be considered to be asserted in either the high state or the low state, and deasserted in the other state.

The core circuit 16 operates according to the V_{Core} supply voltage, and thus signals generated by the core circuit 16 generally swing between V_{Core} and V_{SS}. The level shifter 30 may shift signals that are supplied to the driver circuit 14. Specifically, for example, the signal may be shifted so that it swings between V_{IO} and V_{SS} instead of between V_{Core} and V_{SS}. The level shifting may be used to control transistors in the driver circuit 14 to ensure that the transistors are fully on or fully off when the signal is at the high state. If the signal is V_{Core}, a P-type metal-oxide-semiconductor (PMOS) transistor coupled to V_{IO} may not fully turn off if the signal is provided on the PMOS transistor's gate terminal, for example. By level shifting to V_{IO}, the PMOS transistor may be fully turned off when the control signal is at V_{IO}.

The control circuit 18 may be configured to control the driver circuit 14 (through the level shifter 30) in any desired fashion. For example, the control circuit 18 may be programmable (e.g. in a register) to pull up the output, pull down the output, or tristate the output. Software may write the register to drive the desired values. Alternatively, the control circuit 18 may control the output automatically according to an interface specification for the external device 12. In one embodiment, the output may be a general purpose IO (GPIO) pin that may be connected to any external device and controlled by software.

The core circuitry 16 may generally comprise the circuitry that implements the operation for which the integrated circuit 10 is designed. For example, if the design includes one or more processors, the core circuitry 16 may include the circuitry that implements the processor operation (e.g. instruction fetch, decode, execution, and result write). The processors may include general purpose processors and/or graphics processors in various embodiments. If the design includes a bridge to a peripheral interface, the core circuitry 16 may include the circuitry that implements the bridge operation. If the design includes other communication features such as packet interfaces, network interfaces, etc., core circuitry 16 may include circuitry implementing the corresponding features. The integrated circuit 10 may generally be designed to provide any set of operations. Generally, the core circuitry 16 may comprise any combination of one or more of the following: memory arrays, combinatorial logic, state machines, flops, registers, other clocked storage devices, custom logic circuits, etc.

While one output pin is illustrated explicitly in FIG. 1, there may be multiple output pins of the integrated circuit 10 that are coupled to the device 12, and/or there may be additional pins to which other devices are coupled. The output pin may be an input/output pin (e.g. if a receiver circuit is also coupled to the output pin), and there may also be input pins having additional receiver circuits coupled to the input pins. Other driver circuits similar to the driver circuit 14 and other level shifters similar to the level shifter 30 may be used for pins on which the voltages used to communicate are V_{IO} voltages. Other pins may use V_{Core} voltages for communication, and thus may use different types of driver circuits, as desired.

It is noted that the level shifters may be used within an integrated circuit as well, if the integrated circuit supports multiple voltage domains within the core circuitry 16. The level shifter 30 as shown in FIG. 2 may be used in any level shifting implementation.

The apparatus shown in FIG. 1 may be included in any type of electronic system. For example, the apparatus may be implemented in a mobile computing device, and the external device 12 may include various communications devices (e.g. for cell phone communication, wireless (wifi) communication, global position system (GPS) communication, etc.), devices for audio and video playback, etc.

Turning now to FIG. 2, a circuit diagram illustrating one embodiment of the level shifter 30 is shown. In the embodiment of FIG. 2, the level shifter 30 includes various n-type MOS (NMOS) transistors and PMOS transistors. The standard symbols for NMOS transistors (no open circle on the gate terminal, such as the transistor T1) and PMOS transistors (open circle on the gate terminal, such as transistor T0) are used in FIG. 2 to illustrate the circuit. Thus, transistors T1, T6, T7, T8, T10, T12, and T14 are NMOS in this embodiment and the transistors T0, T2, T3, T4, T5 T9, T11, and T13 may be PMOS in this embodiment. In the illustrated embodiment, three nodes are labeled for reference in the discussion (N1, N2, and N3).

The supply conductors 20, 24, and 26 are powered to the respective voltages V_{SS}, V_{IO}, and V_{Core} as illustrated in FIG. 2, during use. The supply conductors are intended to carry a relatively stable voltage (as opposed to signal conductors, which carry signals that vary to covey information). While the voltage on the conductors may be subject to variance during use (e.g. voltage droop during high current conditions, noise, etc.), the conductors are nominally held at the desired voltage. For example, the conductors may be electrically connected to the V_{Core}, V_{IO}, and V_{SS} input pins of the integrated circuit. The output conductor 22 is also a conductor, and may be connected to the driver circuit 14 in the embodiment of FIG. 1.

As illustrated, the level shifter 30 includes a pair of “low voltage” inverters (that is, inverters that are powered by the V_{Core} supply voltage during use). The inverters are connected in series, and are illustrated as the transistors T11 and T12 (for the first inverter) and T13 and T14 (for the second inverter). The input signal “In” from the control circuit 18 is connected to the input of the first inverter (the gates of the transistors T11 and T12). The output of the first inverter is connected to the input of the second inverter (the gates of the transistors T13 and T14). Additionally, the output of the first inverter is connected to the gate of the transistor T8, and the output of the second inverter is connected to the gate of the transistor T1. The sources of the transistors T1, T6, T8, T10, T12, and T14 are connected to the V_{SS} supply conductor 20. The drain of the transistor T1 is connected to the node N1. The drain of the transistor T6 is connected to the node N2, and the drain of the transistor T8 is connected to the source of the transistor T7. The drain of the transistor T7 is connected to the node N3, and thus the transistors T7 and T8 are coupled in series between the node N3 and the ground node (V_{SS} supply conductor 20). The drain of the transistor T5 is also connected to the node N2, and the gates of the transistors T5 and T6 are connected to the node N1. The source of the transistor T5 is connected to the V_{IO} supply conductor 24. Accordingly, the transistors T5 and T6 form another inverter that is supplied by the V_{IO} supply voltage during use, and has its input connected to the node N1 and its output connected to the node N2. Transistors T0, T2, T3, and T4 have their sources connected to the V_{IO} supply conductor 24. The gate of the transistor T0 is connected to the node N3. The gate of the transistor T2 is connected to the node N1, and the gate of the transistors T3 and T4 are connected to the node N2. The drain of the transistors T0 and T3 are connected to the node N1, while the drain of the transistors T2 and T4 are connected to the node N3. The gate of the transistor T7 is connected to the node N2. The transistor T9 and T10 form an output inverter having an input connected to the node N1 and an output connected to the output conductor 22.

The transistors T0 and T1 may be pullup and pulldown transistors, respectively, provided to rapidly transition the node N1 to a low (V_{SS}) or high (V_{IO}) voltage in response to the input signal “In”. Thus, the transistors T0 and T1 may be larger in size (and drive strength) than the other transistors in the level shifter 30. For example, in one embodiment, the transistor T0 and T1 may be on the order of 6-10 times larger than the transistors T2, T3, and T4, for example.

As described in more detail below, the node N1 may be the inverse of the input signal “In”. The output inverter T9, T10 may buffer and invert the node N1 to provide the output signal “Out”, and thus the output of the level shifter 30 is a level-shifted version of the input signal. Other embodiments may eliminate the output inverter T9, T10 and the node N1 may be the output. In such embodiments, the output of the level shifter 30 may be an inverted, level-shifted version of the input signal.

The level shifter 30 may be approximately “balanced”, so that rise time delay and fall time delay on the output in response to rising edges and falling edges on the input signal “In” may be approximately equal. Such balanced rise and fall delays may be desirable, e.g., when used on output lines in which either signal transition may be important. For example, a rising transition on the input signal “In” passes through the transistors T12, T13, T1, and T9. A falling transition in the input signal “In” passes through T11, T8/T7, T0 and T10. Thus, approximately 4 gate delays are experience for each transition.

Additionally, the keeper transistors T3 and T4 may be used to retain a high transition from the input signal “In”, turning off the transistor T0. The transistor T1 is turned off through the inverter T13, T14 as a falling transition is propagated to the transistor T1. Accordingly, the pullup and pulldown transistors may not drive against each other. The transistor T1 may drive against the relatively small keeper transistor T3, and the transistor T0 may not drive against anything. Accordingly, the level shifter 30 may be power efficient.

A rising transition on the input signal “In” will now be described in more detail, followed by a description of a falling transition. In response to a rising transition, the first inverter T11, T12 drives its output low, and the second inverter T13, T14 drives its output high. The gate of transistor T8 is driven low, turning the transistor T8 off and thus ensuring no current flow through the series connection of the transistors T8 and T7. The gate of the transistor T1 is driven high, turning the transistor T1 on and draining the node N1. The output inverter T9, T10 drives the output “Out” high, to the V_{IO} voltage. Thus, a rising transition on the input signal “In” (transition to the V_{Core} voltage) is level shifted to a rising transition to the V_{IO} voltage.

The discharge of the node N1 is inverted by the inverter T5, T6, charging the gate of the transistor T7 and turning the keeper transistors T4 and T3 off. The transistor T2 is turned on, and the transistor T2 acts as a keeper on node N3, keeping the node N3 high and the transistor T0 off.

For a falling transition on the input signal “In”, the first inverter T11, T12 drives its output high and the second inverter T13, T14 drives its output low, turning off the transistor TI. The gate of the transistor T8 is high, turning transistor T8 on. The gate of the transistor T7 is already on (as mentioned above), and thus the node N3 is discharged. The transistor T0 turns on, pulling up the node N1 to the V_{IO} voltage and turning off the transistor T2. The output inverter T9, T10 drives the output signal “Out” low. The inverter T5, T6 drives the node N2 low, turning on the keeper transistors T3 and T4. The keeper transistor T3 retains the high voltage on the node N1, and the keeper transistor T4 charges the node N3, turning off the transistor T0.

In one embodiment, the transistors T11, T12, T13, and T14 may be “thin gate” transistors. That is, the gate oxide thickness may be the minimum gate oxide thickness (nominally) that is supported by the semiconductor fabrication process that is used to manufacture the IC 10. The transistors T0, T1, T2, T3, T4, T5, T6, T7, T8, T9, and T10 may be thicker gate transistors having thicker gate oxides that than the thin gate transistors. Such transistors may have a higher threshold voltage, but may also be able to withstand the higher V_{IO} supply voltages with significantly lower early life failures than thin gate transistors would have.

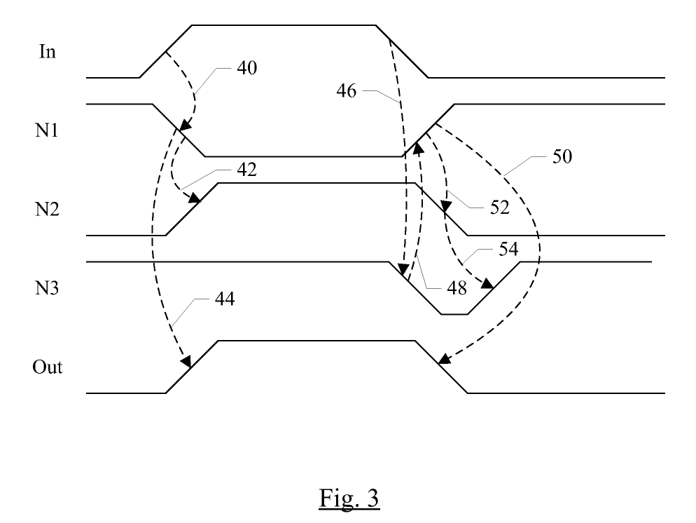

Turning now to FIG. 3, a timing diagram is shown illustrating the voltages at various points on the level shifter 30 as shown in FIG. 2 for a rising transition and a falling transition on the input signal “In”. The nodes N1, N2, and N3 marked on the circuit shown in FIG. 2 are illustrated, long with the output signal “Out”. While the specific voltage levels are not shown in FIG. 3, the In signal swings between V_{SS} and V_{Core}, and the nodes N1, N2, and N3 and the Out signal swing between V_{SS} and V_{IO}.

The In signal transitions high, which causes a transition high on the gate of the transistor T1, which causes the node N1 to discharge (dotted arrow 40). The discharge of the node N1 is inverted by the inverter T5, T6, discharging the node N2 (dotted arrow 42). Additionally, the discharge of the node N1 is inverted by the inverter T9, T10, causing the Out signal to rise (dotted arrow 44).

Subsequently, the In signal transitions low. The gate of the transistor T8 is driven high, and the gate of the transistor T7 (node N2) is high, causing a discharge of the node N3 (dotted arrow 46). The discharge of the node N3 turns on the transistor T0, which charges the node N1 (dotted arrow 48). The charging of node N1 is inverted by the output inverter T9, T10 and the Out signal falls (dotted arrow 50). Additionally, the rising voltage on the node N1 is inverted by the inverter T5, T6, discharging the node N2 (dotted arrow 52). The discharge of the node N2 turns of the transistor T7 and turns on the keeper transistors T3 and T4. The keeper transistor T4 charges the node N3, turning of the transistor T0 (dotted arrow 54). The keeper transistor T3 retains the high voltage on the node N1.

Numerous variations and modifications will become apparent to those skilled in the art once the above disclosure is fully appreciated. It is intended that the following claims be interpreted to embrace all such variations and modifications.

1. A level shifter comprising:
a first inverter having an input connected to receive an input signal to the level shifter;
a second inverter having an input connected to an output of the first inverter, wherein the first and second inverters are powered, during use, by a first power supply voltage having a first magnitude;
a first transistor having a gate connected to an output of the second inverter, a source connected to a ground node, and a drain connected to a first node;
a second transistor having a gate connected to the output of the first inverter and a source connected to the ground node;
a third transistor having a source connected to a drain of the second transistor and a drain connected to a second node; and
a fourth transistor having a gate connected to the second node, a source connected to a second power supply node powered, during use, to a second power supply voltage having a second magnitude, and a drain connected to the first node, wherein the second magnitude is greater than the first magnitude.

2. The level shifter as recited in claim 1 further comprising an output inverter having an input connected to the first node and powered, during use, by the second power supply, wherein an output of the output inverter is an output of the level shifter.

3. The level shifter as recited in claim 1 further comprising a third inverter having an input connected to the first node and an output connected to a gate of the third transistor, wherein the third inverter is powered, during use, by the second power supply voltage.

4. The level shifter as recited in claim 3 further comprising a fifth transistor having a gate connected to the output of the third inverter, a source connected to the second power supply node, and a drain connected to the first node.

5. The level shifter as recited in claim 4 further comprising a sixth transistor having a gate connected to the output of the third inverter, a source connected to the second power supply node, and a drain connected to the second node.

6. The level shifter as recited in claim 5 further comprising a seventh transistor having a gate connected to the first node, a drain connected to the second node, and a source connected to the second power supply node.

7. The level shifter as recited in claim 1 wherein transistors forming the first inverter and the second inverter have a first gate thickness and the remaining transistors in the level shifter have a second gate thickness that is greater than the first.

8. A level shifter comprising:
a first inverter and a second inverter connected in series, wherein the first and second inverters are powered, during use, by a first power supply voltage having a first magnitude, and wherein the first inverter has an input connected to receive an input signal to the level shifter;
a pulldown transistor having a gate connected to an output of the second inverter, a source connected to a ground node, and a drain connected to a first node;
a series connection of a second transistor and a third transistor, the second transistor having a gate connected to an output of the first inverter, and the series connection connected between the ground node and a second node;
a third inverter having an input connected to the first node and an output connected to a gate of the third transistor, wherein the third inverter is powered, during use, by a second power supply voltage having a second magnitude, wherein the second magnitude is greater than the first magnitude; and
a pullup transistor having a gate connected to the second node, a source connected to a second power supply node powered, during use, to the second power supply voltage, and a drain connected to the first node.

9. The level shifter as recited in claim 1 further comprising an output inverter having an input connected to the first node and powered, during use, by the second power supply, wherein an output of the output inverter is an output of the level shifter.

10. The level shifter as recited in claim 8 further comprising a pair of keeper transistors having sources connected to the second power supply node and gates connected to the output of the third inverter, wherein a drain of one of the pair is connected to the first node and a drain of the other one of the pair is connected to the second node.

11. The level shifter as recited in claim 10 further comprising a fifth transistor having a gate connected to the first node, a drain connected to the second node, and a source connected to the second power supply node.

12. An integrated circuit comprising:
core circuitry powered, during use, by a first supply voltage having a first magnitude;
driver circuitry powered, during use, by a second supply voltage having a second magnitude greater than the first magnitude; and
a level shifter coupled between the core circuitry and the driver circuitry, the level shifter comprising:
a first inverter having an input connected to receive an input signal to the level shifter;
a second inverter having an input connected to an output of the first inverter, wherein the first and second inverters are powered, during use, by the first power supply voltage;
a first transistor having a gate connected to an output of the second inverter, a source connected to a ground node, and a drain connected to a first node;
a second transistor having a gate connected to the output of the first inverter and a source connected to the ground node;
a third transistor having a source connected to a drain of the second transistor and a drain connected to a second node;
a third inverter having an input connected to the first node and an output connected to a gate of the third transistor, wherein the third inverter is powered, during use, by the second power supply voltage;
a fourth transistor having a gate connected to the second node, a source connected to a second power supply node powered, during use, to the second power supply voltage, and a drain connected to the first node; and
an output inverter having an input connected to the first node and powered, during use, by the second power supply, wherein an output of the output inverter is an output of the level shifter connected to the driver circuit.

13. The integrated circuit as recited in claim 12 wherein the level shifter further comprises a fifth transistor having a gate connected to the output of the third inverter, a source connected to the second power supply node, and a drain connected to the first node.

14. The integrated circuit as recited in claim 13 wherein the level shifter further comprises a sixth transistor having a gate connected to the output of the third inverter, a source connected to the second power supply node, and a drain connected to the second node.

15. The integrated circuit as recited in claim 14 wherein the level shifter further comprises a seventh transistor having a gate connected to the first node, a drain connected to the second node, and a source connected to the second power supply node.

16. The integrated circuit as recited in claim 12 wherein transistors forming the first inverter and the second inverter have a first gate thickness and the remaining transistors in the level shifter have a second gate thickness that is greater than the first.

17. A level shifter comprising:
a first inverter having an input connected to receive an input signal to the level shifter;
a second inverter having an input connected to an output of the first inverter, wherein the first and second inverters are powered, during use, by a first power supply voltage having a first magnitude;
a first N-type metal-oxide-semiconductor (NMOS) transistor having a gate connected to an output of the second inverter, a source connected to a ground node, and a drain connected to a first node;
a second NMOS transistor having a gate connected to the output of the first inverter and a source connected to the ground node;
a third NMOS transistor having a source connected to a drain of the second NMOS transistor and a drain connected to a second node;
a third inverter having an input connected to the first node and an output connected to a gate of the third NMOS transistor, wherein the third inverter is powered, during use, by a second power supply voltage, having a second magnitude, wherein the second magnitude is greater than the first magnitude;
a first p-type MOS (PMOS) transistor having a gate connected to the second node, a source connected to a second power supply node powered, during use, to the second power supply voltage, and a drain connected to the first node;
a second PMOS transistor having a gate connected to the output of the third inverter, a source connected to the second power supply node, and a drain connected to the first node;
a third PMOS transistor having a gate connected to the output of the third inverter, a source connected to the second power supply node, and a drain connected to the second node; and
a fourth PMOS transistor having a gate connected to the first node, a drain connected to the second node, and a source connected to the second power supply node; and
wherein a first delay from the first inverter through the second inverter and the first NMOS transistor to the first node is approximately equal to a second delay from the first inverter through the second NMOS transistor in series with the third NMOS transistor and the first PMOS transistor to the first node.

18. The level shifter as recited in claim 17 further comprising an output inverter having an input connected to the first node and powered, during use, by the second power supply, wherein an output of the output inverter is an output of the level shifter.
